(19) United States
(12) Patent Application Publication
(10) Pub. No.: US 2016/0143139 A1
(43) Pub. Date: May 19, 2016

(54) ELECTRONIC COMPONENT DEVICE AND METHOD FOR MANUFACTURING THE SAME

(71) Applicant: Shinko Electric Industries Co., Ltd., Nagano-shi (JP)

(72) Inventors: Haruo Sorimachi, Nagano-shi (JP); Tetsuya Koyama, Nagano-shi (JP)

(21) Appl. No.: 14/938,091

(22) Filed: Nov. 11, 2015

(30) Foreign Application Priority Data
Nov. 13, 2014 (JP) 2014-230941

(51) Int. Cl. H05K 1/11; H05K 1/09; H05K 1/18; H05K 1/02

(52) U.S. Cl. CPC H05K 1/11; H05K 1/0298; H05K 1/115; H05K 1/09; H05K 1/181

(57) ABSTRACT

An electronic component device includes a first insulating layer, a wiring layer, a second insulating layer, a wiring component, and first and second electronic components. The first insulating layer includes a mounting region on an upper surface thereof. The wiring layer is formed on the first insulating layer except the mounting region. The second insulating layer is formed on the first insulating layer, is formed with an opening in the mounting region, and is formed with first and second connection holes on the wiring layer. The wiring component is mounted in the mounting region and in the opening and includes first and second connecting portions. The first electronic component is connected to the first connecting portion and is connected to the wiring layer in the first connection hole. The second electronic component is connected to the second connecting portion and is connected to the wiring layer in second connection hole.

### CROSS-REFERENCE TO RELATED APPLICATION(S)

This application claims priority from Japanese Patent Application No. 2014-230941, filed on Nov. 13, 2014, the entire contents of which are herein incorporated by reference.

### BACKGROUND

1. Field

Exemplary embodiments of the invention relate to an electronic component device and a method for manufacturing the electronic component device.

2. Related Art

In one electronic component device for use in an electronic apparatus, electronic components are mounted on a wiring board. In another electronic component device, two electronic components are mounted on a wiring board to be juxtaposed to each other, and the two electronic components are connected to each other through fine wirings.

Examples of a method for connecting two electronic components to each other include a method of providing a wiring component having fine wirings on a wiring board and a method of forming fine wirings in a wiring board.

### SUMMARY

As will be described in preliminary matters later, a wiring board in which two semiconductor chips are connected to each other through a wiring component may require connecting connection terminals of the semiconductor chips to the wiring board and the wiring component placed on the wiring board.

Therefore, it is necessary that the connection terminals of the semiconductor chips to be connected to the wiring board have a height which is equal to or larger than a thickness of the wiring component. If a pitch of the connection terminals of the semiconductor chips is narrowed, particularly, it is difficult to form the connection terminals and the reliability of the connection with the wiring board is not ensured.

One exemplary embodiment of the invention provides an electronic component device having a structure that two electronic components are connected to each other through a wiring component with high reliability and a method for manufacturing the electronic component device.

An electronic component device may include a first insulating layer, a wiring layer, a second insulating layer, a wiring component, a first electronic component, and a second electronic component. The first insulating layer includes a mounting region on an upper surface thereof. The wiring layer is formed on the first insulating layer except the mounting region. The second insulating layer is formed on the first insulating layer, is formed with an opening in the mounting region, and is formed with first and second connection holes on the wiring layer. The wiring component is mounted in the mounting region and in the opening of the second insulating layer and includes first and second connecting portions. The first electronic component is connected to the first connecting portion of the wiring component and is connected to the wiring layer in the first connection hole. The second electronic component is connected to the second connecting portion of the wiring component and is connected to the wiring layer in second connection hole.

According to the following disclosures, in a wiring board of an electronic component device, a wiring layer is not formed in a mounting region of a first insulating layer. An opening of a second insulating layer is provided in the mounting region of the first insulating layer.

Then, a wiring component is mounted in the mounting region of the first insulating layer which is exposed to the opening of the second insulating layer. Therefore, a level of an upper surface of the wiring component is set to a lower level by a thickness of the wiring layer and a thickness of the second insulating layer.

Therefore, a level difference between the upper surface of the wiring layer and the upper surface of the wiring component can be made small. As a result, a height of connection terminals of the electronic component connected to the wiring layer can be lowered.

Consequently, connection terminals having different heights in an electronic component can be connected to the wiring layer of the wiring board and the wiring component with high reliability.

### BRIEF DESCRIPTION OF DRAWINGS

FIG. 1 is a section view showing an electronic component device according to preliminary matters;

FIGS. 2A and 2B are section views (No. 1) showing a method for manufacturing a wiring board according to one exemplary embodiment;

FIGS. 3A and 3B are section views (No. 2) showing the method for manufacturing the wiring board according to the exemplary embodiment;

FIGS. 4A and 4B are section views (No. 3) showing the method for manufacturing the wiring board according to the exemplary embodiment;

FIG. 5 is a section view showing the wiring board according to the exemplary embodiment;

FIG. 6 is a section view showing an example of a wiring component to be mounted on the wiring board according to the exemplary embodiment;

FIGS. 7A and 7B are section views showing how the wiring component is mounted on the wiring board;

FIG. 8 is a reduced plan view of the wiring board of FIG. 5 when viewed from above;

FIG. 9 is a section view (No. 1) showing a method for manufacturing an electronic component device by mounting electronic components on the wiring board of FIG. 5;

FIG. 10 is a section view (No. 2) showing the method for manufacturing the electronic component device by mounting the electronic components on the wiring board of FIG. 5; and

FIG. 11 is a section view showing the electronic component device according to the exemplary embodiment.

### DETAILED DESCRIPTION

Hereinafter, exemplary embodiments will be described with reference to the accompanying drawings.

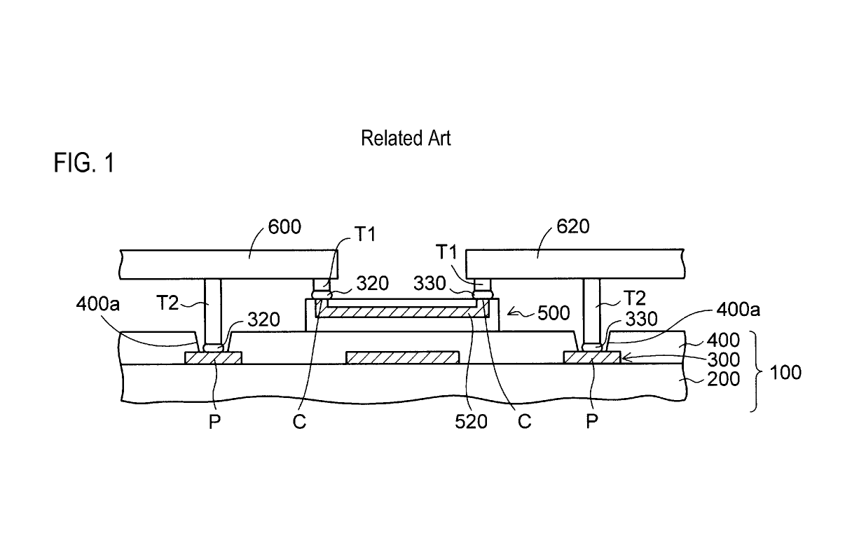

Before description is given on the exemplary embodiments, preliminary matters underlying one exemplary embodiment of the invention will be described. FIG. 1 is a partially section view showing an electronic component device according to the preliminary matters.

As shown in FIG. 1, in a wiring board 100 of the electronic component device, a wiring layer 300 including pads P is formed on an insulating layer 200. Also, a solder resist layer 400 is formed on the insulating layer 200. The solder resist layer 400 is formed with openings 400a on the pads P.

Furthermore, a wiring component 500 is fixed onto the solder resist layer 400 by an adhesive agent (not shown). The wiring component 500 incorporates fine-wiring layers 520. Connecting portions C of the fine-wiring layers 520 are formed on an upper surface of the wiring component 500.

A first connection terminal T1 of a first semiconductor chip 600 is connected to one of the connecting portions C of the wiring component 500 by a solder 320. A second connection terminal T2 of the first semiconductor chip 600 is connected to one of pads P of the wiring board 100 by the solder 320.

Similarly, a first connection terminal T1 of a second semiconductor chip 620 is connected to the other connecting portion C of the wiring component 500 by a solder 330. A second connection terminal T2 of the second semiconductor chip 620 is connected to the other pad P of the wiring board 100 by the solder 330.

In this manner, the first semiconductor chip 600 and the second semiconductor chip 620 are connected to each other through the fine-wiring layers 520 of the wiring component 500.

The wiring component 500 is placed on the solder resist layer 400. Therefore, the whole thickness of the wiring component 500 constitutes a step.

In order to connect the second connection terminal T2 of the first semiconductor chip 600 to the pad P of the wiring board 100, a height of the second connection terminals T2 should be equal to or higher than the step formed by the wiring component 500.

By contrast, if the first connection terminal T1 of the first semiconductor chip 600 is to be connected to the connecting portion C of the wiring component 500, it is not necessary to consider the step formed by the wiring component 500. Therefore, a height of the first connection terminal T1 of the first semiconductor chip 600 is considerably low.

Because of the thickness of the wiring component 500, the height of the second connection terminal T2 of the first semiconductor chip 600 is considerably higher than that of the first connection terminals T1.

For example, respective elements may have the following dimensions: the thickness of the wiring component 500 is 50 μm; that of the adhesive agent (not shown) under the wiring component 500 is 10 μm; that of the pads P of the wiring board 100 is 15 μm; and that of the solder resist layer 400 measured from upper surfaces of the pads P is 20 μm.

In this case, the height from the upper surfaces of the pads P of the wiring board 100 to upper surfaces of the connecting portions C of the wiring component 500 is as high as 80 μm.

It is necessary that the second connection terminal T2 of the first semiconductor chip 600 is high enough so as to be compatible with the above-described height of 80 μm. If the wiring component 500 and the solder resist layer 400 have a further thickness, a level difference therebetween is further increased.

In accordance with recent enhancement of performance of semiconductor chips, the pitch of connection terminals is narrowed. If the pitch of connection terminals of a semiconductor chip is narrowed, particularly, it is difficult to form tall connection terminals having a height of 75 μm or more.

If a height difference among connection terminals of a semiconductor chip is large, the reliabilities of connections among the semiconductor chip, and a wiring board and a wiring component are not ensured. Also, it is difficult to simultaneously form connection terminals having different heights if the height difference therebetween is large. In this case, the connection terminals are formed in two steps, which results in cost increase.

Therefore, a wiring board having a structure that a height of connection terminals of a semiconductor chip is lowered to ensure the connection reliability is desired.

Some of the exemplary embodiments which will be described below have been made in view of the above circumstances.

### Exemplary Embodiments

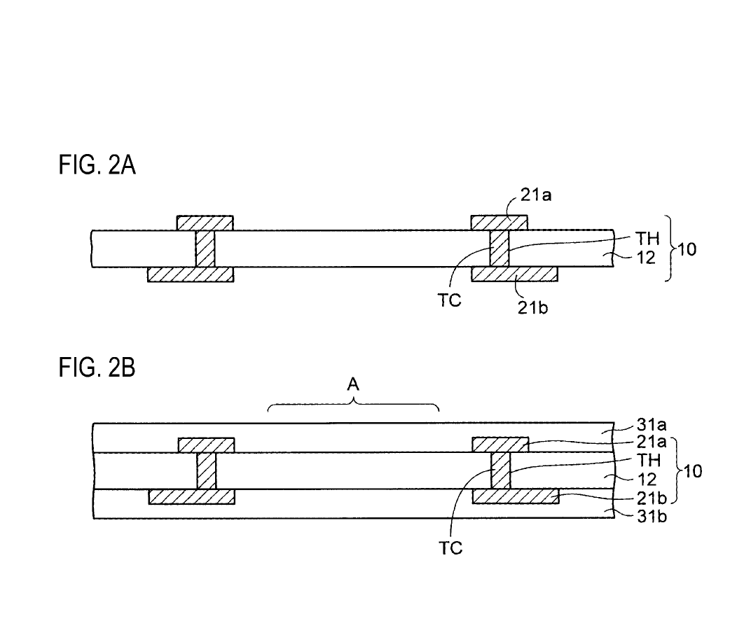

FIGS. 2 to 10 are views illustrating a wiring board and an electronic component device according to one exemplary embodiment. Hereinafter, the structures of the wiring board and the electronic component device will be described while description will be given on methods for manufacturing the wiring board and the electronic component device.

In the method for manufacturing the wiring board according to a first exemplary embodiment, at first, a core substrate 10 having a structure shown in FIG. 2A is prepared. The core substrate 10 includes an insulating substrate 12 which is made of a glass epoxy resin or the like. The insulating substrate 12 is formed with through holes TH. The through holes TH pass through the insulating substrate 12 in a thickness direction thereof. The through holes TH are filled with through conductors TC, respectively.

First wiring layers 21a, 21b are formed on both surfaces of the core substrate 10, respectively. The first wiring layers 21a, 21b on the both surfaces are connected to each other through the through conductors TC.

Alternatively, through hole plating layers may be formed on side walls of the through holes TH. In this case, the remaining portions of the through holes TH may be filled with a resin.

The through holes TH of the core substrate 10 are formed by drilling or the like. The first wiring layers 21a, 21b and the through conductors TC of the core substrate 10 are formed by a plating method, photolithography, or the like.

As shown in FIG. 2B, next, uncured resin films are applied to the both surface of the core substrate 10. Then, the resin films are cured by heat treatment to form insulating layers 31a, 31b on the both surfaces of the core substrate 10. The insulating layers 31a, 31b may be made of an epoxy resin, a polyimide resin, or the like. The insulating layer 31a is an example of a first insulating layer.

A mounting region “A” which is used in later mounting of a wiring component is defined on an upper face of the insulating layer 31a. In other words, the insulating layer 31a includes the mounting region “A” on the upper surface thereof.

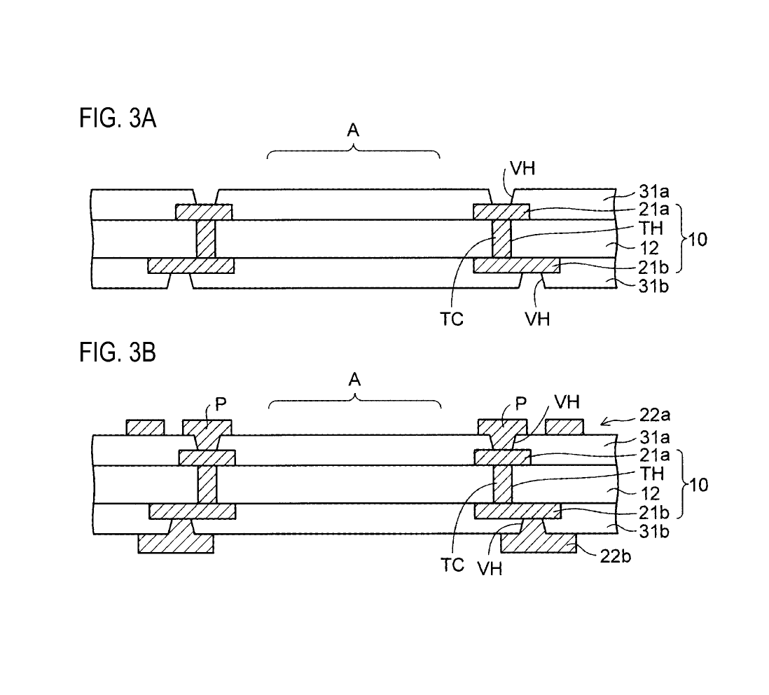

As shown in FIG. 3A, then, the insulating layers 31a, 31b on the both surfaces of the core substrate 10 except the wiring component mounting region “A” on the insulating layer 31a is processed with a laser so as to form via holes VH. The via holes VH reach the respective first wiring layers 21a, 21b.

As shown in FIG. 3B, second wiring layers 22a, 22b are formed on the insulating layers 31a, 31b on the both sides of the core substrate 10, respectively. The second wiring layers 22a, 22b are connected to the respective first wiring layers 21a, 21b through via conductors provided in the via holes VH. The second wiring layer 22a is formed in a region on the insulating layer 31a except the wiring component mounting region “A.”

FIG. 3B shows pads P of the second wiring layers 22a, 22b. The second wiring layer 22a on the upper surface side of the core substrate 10 includes wirings and the pads P. However, in the drawings, only the pads P will be shown and the wirings will be omitted.

The second wiring layers 22a, 22b may be pads having island shapes. Alternatively, the second wiring layers 22a, 22b may be provided so that ends of lead-out wirings are connected to pads.

The second wiring layers 22a, 22b are formed by a semi-additive process. Specifically, seed layers (not shown) made of copper or the like are firstly formed on the insulating layers 31a, 31b and inner surfaces of the via holes VH by an electroless plating process or a sputtering process.

Then, a plating resist layer (not shown) is formed. The plating resist layer is provided with openings in regions where the second wiring layers 22a, 22b are to be formed. Metal plating layers (not shown) made of copper or the like are formed in the openings of the plating resist layer by an electrolytic plating process. The electrolytic plating process uses the seed layer as a plating power supply path.

The plating resist layer is removed. Then, the seed layer is removed by wet etching while using the metal plating layers as a mask.

As result, the second wiring layers 22a, 22b including the seed layer and the metal plating layer are formed.

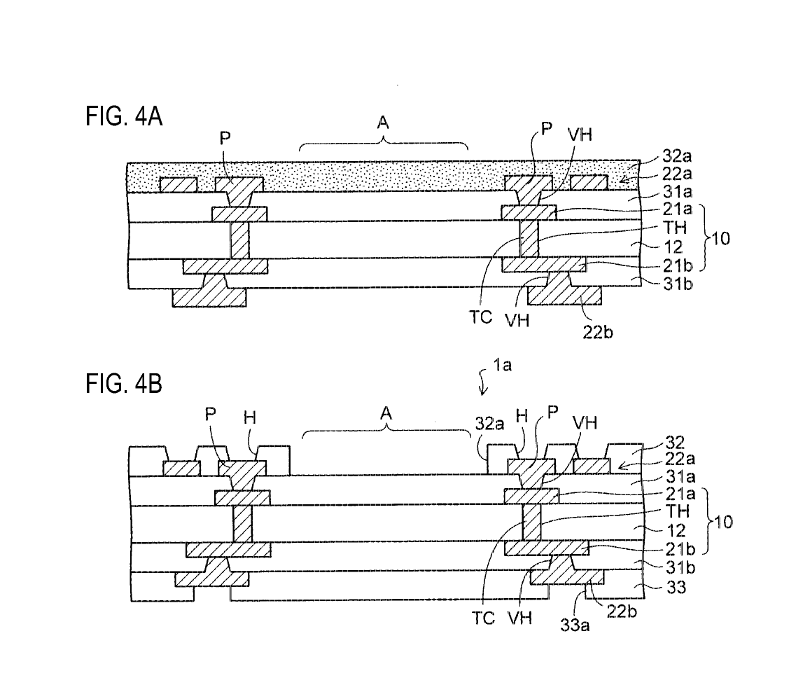

As shown in FIG. 4A, then, a photosensitive solder resist material 32a is formed on the pads P and insulating layer 31a, 31b on the upper surface side of the core substrate 10. The photosensitive solder resist material 32a may be formed by applying a liquid solder resist material or by laminating a film solder resist material.

The solder resist material 32a is exposed by photolithography and developed. As a result, a solder resist layer 32 is formed as shown in FIG. 4B. The solder resist layer 32 is formed with an opening 32a on the wiring component mounting region A. Also, the solder resist layer 32 is formed with connection holes H on the pads P.

The solder resist layer 32 is an example of a second insulating layer. The second insulating layer is formed as an uppermost protective insulating layer. In place of the solder resist layer 32, various insulating materials may be used as the second insulating layer.

A solder resist layer 33 is formed on the insulating layer 31b on the lower surface side of the core substrate 10. The solder resist layer 33 is formed with openings 33a on connecting portions of the second wiring layer 22b.

In this manner, none of the second wiring layer 22a (pads P) and the solder resist layer 32 is formed in the wiring component mounting region A of the insulating layer 31a. Also, the whole of the wiring component mounting region “A” is formed as a vacant space through which the insulating layer 31a is exposed.

As a result, a base wiring board 1a is obtained. The base wiring board 1a has the structure that the insulating layer 31a is exposed through the wiring component mounting region “A,” which is defined in the opening 32a of the uppermost solder resist layer 32. In the example of the base wiring board 1a of FIG. 4B, multilayer wiring layer (the first and second wiring layers 21a, 21b, 22a, 22b) each having the two layers are formed on the both surfaces of the insulating substrate 12. However, the number of stacked layers in the multilayer wiring layer may be arbitral.

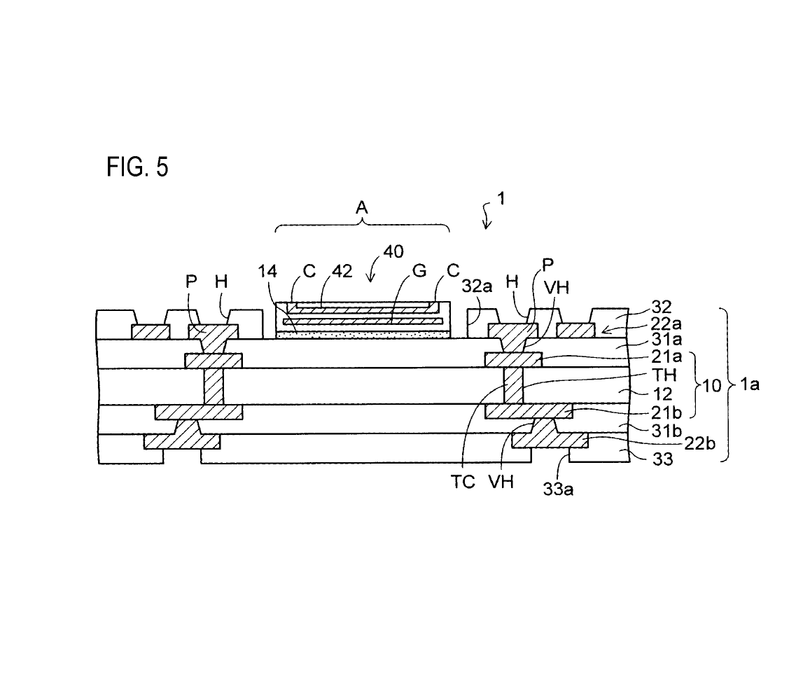

Next, a wiring component 40 is mounted and fixed in the wiring component mounting region “A” of the insulating layer 31a by an adhesive agent 14 as shown in FIG. 5.

The wiring component 40 internally includes fine internal wiring layers 42. Also, connecting portions C of the internal wiring layers 42 are exposed and disposed on an upper surface of the wiring component 40. A ground layer G is formed inside the wiring component 40. Although not particularly illustrated, a connecting portion of the ground layer G is similarly exposed and disposed on the upper surface of the wiring component 40.

For example, a line (width) and space (interval) (that is, L/S) of the internal wiring layers 42 of the wiring component 40 is 2 μm/2 μm. By contrast, a line and space (L/S) of the second wiring layers 22a, 22b of the base wiring board 1a is, for example, 10 μm/10 μm.

As described above, in order to connect semiconductor chips having narrow-pitch connection terminals to each other, the pitch of the internal wiring layers 42 of the wiring component 40 is narrower than that of the second wiring layers 22a, 22b of the base wiring board 1a.

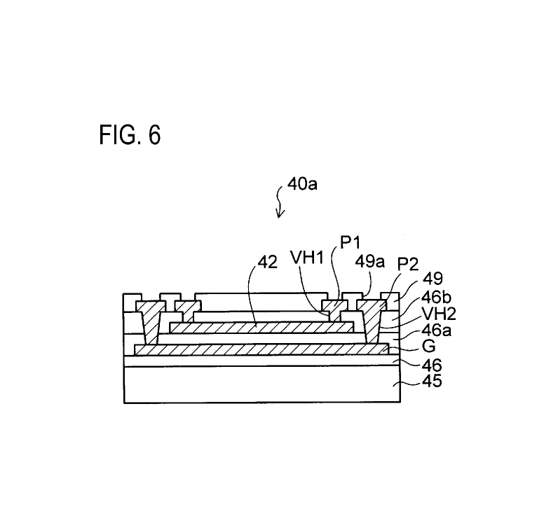

FIG. 6 shows a specific example of the wiring component 40. As shown in FIG. 6, a silicon-based wiring component 40a is employed as the wiring component 40. In the silicon-based wiring component 40a, silicon is used as a substrate. Also, in the silicon-based wiring component 40a, a first insulating layer 46, the ground layer G, a second insulating layer 46a, the internal wiring layer 42, and a third insulating layer 46b are sequentially stacked on a silicon substrate 45.

The third insulating layer 46b is formed with first via holes VH1. The first via holes VH1 reach the internal wiring layer 42. Also, the third insulating layer 46b and the second insulating layer 46a are formed with second via holes VH2. The second via holes VH2 reach the ground layer G.

Connection pads P1 are formed on the third insulating layer 46b. The connection pads P1 are connected to the internal wiring layer 42 through via conductors provided in the first via holes VH1. Connection pads P2 are formed on the third insulating layer 46b. The connection pads P2 are connected to the ground layer G through via conductors provided in the second via holes VH2.

A protective insulating layer 49 is formed on the third insulating layer 46b. The protective insulating layer 49 is formed with openings 49a on the respective connection pads P1, P2. A distance between the connection pads P1 and an upper surface of the protective insulating layer 49 (an upper surface of the wiring component 40a) is equal to or less than a distance between the internal wiring layer 42 and the upper surface of the protective insulating layer 49.

Connection terminals of a first semiconductor chip are connected to the connection pads P1, P2 on one end side of the silicon-based wiring component 40a, respectively. Also, connection terminals of a second semiconductor chip are connected to the connection pads P1, P2 on the other end side of the silicon-based wiring component 40a, respectively.

In this manner, the first and second semiconductor chips are connected to each other through the silicon-based wiring component 40a.

In place of the silicon-based wiring component 40a, various wiring components which use ceramics, a polyimide film, or the like as a substrate may be employed.

Also, the pads P1 may be omitted, and parts of the internal wiring layer 48 may be exposed through the openings 49a and the via holes VH1 to serve as the connecting portions C. In this case, the distance between the connection portions C and the upper surface of the wiring component 40a is equal to the distance between the internal wiring layer 48 and the upper surface of the wiring component 40a.

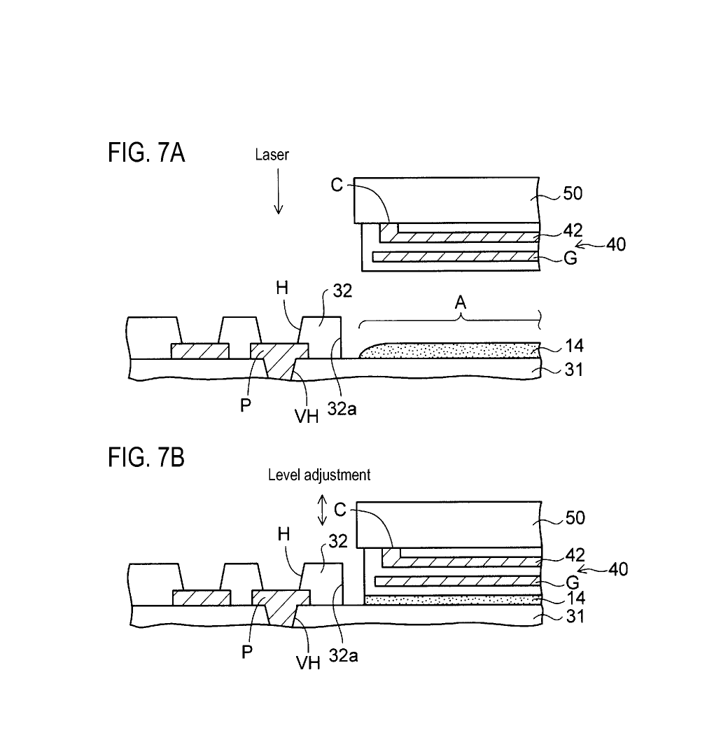

Next, the method for mounting the wiring component 40 of FIG. 5 will be described with reference to partial enlarged views shown in FIGS. 7A and 7B. As shown in FIG. 7A, at first, the adhesive agent 14 is applied to the wiring component mounting region “A” of the insulating layer 31a. An epoxy resin adhesive agent may be used as the adhesive agent 14. For example, a thickness of the applied adhesive agent 14 is in a range of about 20 μm to about 30 μm.

Then, the upper surface of the wiring component 40 is fixed to a mounting tool 50 as shown in FIG. 7A. The wiring component 40 is mounted in the following manner. That is, while the level of the upper surfaces of the pads P of a wiring board 1 is used as a reference, the upper surface of the wiring component 40 is placed at a predetermined level from the upper surfaces of the pads P.

Referring to FIG. 7B as well as FIG. 7A, a height of the upper surfaces of the pads P of the wiring board 1 is measured by a laser height measuring apparatus. The level of the connecting portions C of the wiring component 40 with respect to the pads P is adjusted using the measurement result.

The level of the wiring component 40 may be adjusted by causing the wiring component 40, which is fixed to the mounting tool 50, to abut against the adhesive agent 14 and pressing down or lifting up the wiring component 40.

The connection terminals of the semiconductor chip are simultaneously connected to the pads P of the wiring board 1 and the connecting portions C of the wiring component 40, which have different heights. The thicknesses of the pads P of the wiring board 1, the wiring component 40, the adhesive agent 14, the solder resist layer 32, and the like would vary due to manufacturing tolerance. The thickness variation is an intra-substrate variation or an inter-substrate variation.

Therefore, the level of the wiring component 40 is adjusted so that the levels of the connecting portions C of the wiring component 40 vary as little as possible with respect to the levels of the pads P of the wiring board 1. Thereby, when the connection terminals of the semiconductor chips are connected to the pads P of the wiring board 1 and the connecting portions C of the wiring component 40 at a later step, the connection terminals of the semiconductor chips can be connected with high reliability while the connections are prevented from being opened.

After the level of the wiring component 40 is adjusted, the mounting tool 50 is detached from the wiring component 40. Then, heat treatment is performed to cure the adhesive agent 14.

As a result, the wiring board 1 according to the exemplary embodiment is obtained as shown in FIG. 5. In the wiring board 1, the wiring component 40 is mounted in the wiring component mounting region “A” of the base wiring board 1a.

In the wiring board 1 according to the exemplary embodiment, as shown in FIG. 5, the insulating layers 31a, 31b are formed on the both surface sides of the core substrate 10, which has been described with reference to FIG. 2A. The insulating layers 31a, 31b are formed with the via holes VH on the first wiring layers 21a, 21b, respectively.

The second wiring layers 22a, 22b are respectively formed on the insulating layers 31a, 31b on the both surface sides of the core substrate 10. The second wiring layers 22a, 22b are connected to the respective first wiring layers 21a, 21b through the via conductors provided in the via holes VH. The second wiring layer 22a, which is on the upper surface side of the core substrate 10, is provided in the region of the insulating layer 31a except the wiring component mounting region “A.”

The solder resist layer 33 is formed on the insulating layer 31b on the lower surface side of the core substrate 10. The solder resist layer 33 is formed with the openings 33a on the connecting portions of the second wiring layer 22b.

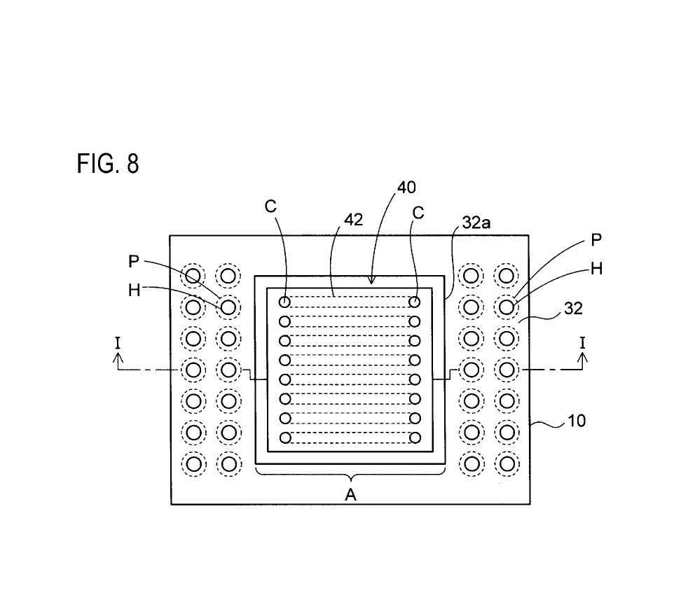

FIG. 8 is a reduced plan view of the wiring board 1 of FIG. 5 when viewed from above. A section taken along a line I-I in FIG. 8 corresponds to the section view of FIG. 5.

Referring to the reduced plan view of FIG. 8 in addition to FIG. 5, the solder resist layer 32 is formed on the insulating layer 31a on the upper surface side of the core substrate 10. The solder resist layer 32 is an example of the uppermost protective insulating layer. The solder resist layer 32 is formed with the opening 32a in the wiring component mounting region “A” of the insulating layer 31a. Also, the solder resist layer 32 is formed with the connection holes H on the pads P.

As shown in the reduced plan view of FIG. 8, groups of the plural connection holes H are provided across the wiring component mounting region “A” from each other. The plural connection holes H of each group are arranged in two columns. The pads P are provided below the connection holes H, respectively.

In the wiring component mounting region “A” of the insulating layer 31a, none of the second wiring layers 22a (pads P) and the solder resist layer 32 is formed. Also, in the wiring component mounting region “A” of the insulating layer 31a, the insulating layer 31a is exposed through the entire opening 32a of the solder resist layer 32.

The wiring component 40 is mounted on and fixed, by the adhesive agent 14, to the insulating layer 31a in the opening 32a of the solder resist layer 32.

With this configuration, the level of the upper surface of the wiring component 40 is lower than that of the upper surface of the wiring component 500 according to the preliminary matters, by the thickness of the pads P and the thickness of the solder resist layer 32.

Therefore, the level difference between the upper surfaces of the pads P of the wiring board 1 and the upper surface of the wiring component 40 can be made small. As a result, the height of the connection terminals of the semiconductor chips connected to the pads P of the wiring board 1 can be made lower than that in the structure according to the preliminary matters.

Moreover, the level of the wiring component 40 is adjusted by using the level of the pads P of the wiring board 1 as a reference. Therefore, the height from the upper surfaces of the pads P of the wiring board 1 to the upper surface of the wiring component 40 can be controlled to be constant.

Therefore, the connection terminals having different heights in the semiconductor chips can be connected to the pads P of the wiring board 1 and the wiring component 40 with high reliability.

The thickness of the wiring component 40 is larger than that of the pads P. Therefore, even if the wiring component 40 is mounted in the opening 32a of the solder resist layer 32, the level of the upper surface of the wiring component 40 is higher than that of the upper surfaces of the pads P.

As shown in the reduced plan view of FIG. 8, the wiring component 40 has a rectangular shape. Also, the internal wiring layers 42 are formed so as to extend from the one end side of the wiring component 40 to the other end side of the wiring component 40. The plural internal wiring layers 42 are arranged to be juxtaposed in up and down directions on the sheet of FIG. 8. The connecting portions C connected to the both ends of the internal wiring layers 42 are exposed.

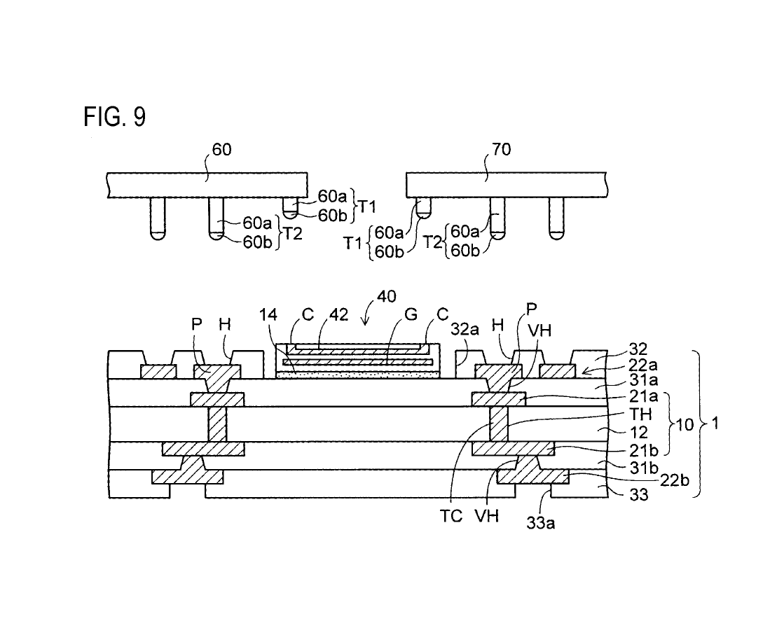

Next, a method for manufacturing an electronic component device by using the wiring board 1 (shown in FIGS. 5 and 8) according to the exemplary embodiment will be described. As shown in FIG. 9, at first, a first semiconductor chip 60 and a second semiconductor chip 70 are prepared. Each of the first and second semiconductor chips 60, 70 includes first connection terminals T1 and second connection terminals T2. The first connection terminals T1 of the first and second semiconductor chips 60, 70 are to be connected to the connecting portions C of the wiring component 40. Therefore, heights of first connection terminals T1 are relatively low.

On the other hand, the second connection terminals T2 of the first and second semiconductor chips 60, 70 are to be connected to the pads P of the wiring board 1. Therefore, heights of the second connection terminals T2 are relatively high. More specifically, the heights of the second connection terminals T2 is larger than those of the first connection terminals T1.

Each of the first connection terminals T1 and second connection terminals T2 of the first and second semiconductor chips 60, 70 includes a copper pillar 60a and a solder 60b. The solder 60b is disposed at a distal end of the copper pillar 60a. The copper pillar 60a and the solder 60b are formed by, for example, a plating process.

Each of the first connection terminals T1 and second connection terminals T2 of the first and second semiconductor chips 60, 70 has 5 μm to 70 μm in diameter and, for example, 20 μm. The arrangement pitch of the first connection terminals T1 connected to the wiring component 40 is in a range of 30 μm to 70 μm and, for example, about 50 μm. In FIG. 9, only one first connection terminal T1 is shown for each of the first and second semiconductor chips 60, 70. However, actually, plural first connection terminals T1 are provided.

The arrangement pitch of the second connection terminals T2 connected to the pads P of the wiring board 1 is in a range of 30 μm to 120 μm and, for example, 80 μm.

Also, the thickness of the solders 60b provided at the distal ends of the first and second connection terminals T1, T2 is in a range of 2 μm to 30 μm and, for example, 25 μm.

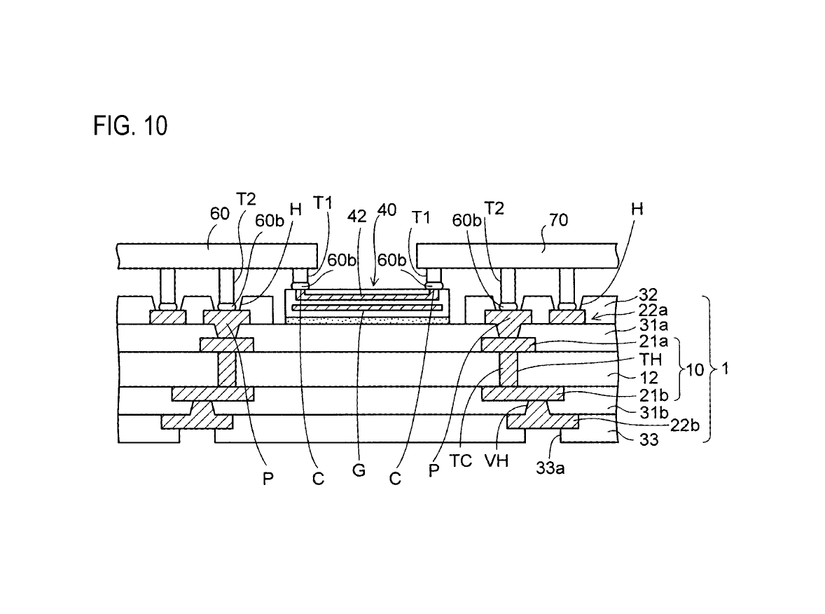

Next, as shown in FIG. 10, the first semiconductor chip 60 is fixed to a chip mounter (not shown). Then, the first semiconductor chip 60 is placed on the wiring board 1 and one end portion of the wiring component 40.

Referring to the reduced plan view of FIG. 8 in addition to FIG. 10, at this time, the solders 60b of the first connection terminals T1 of the first semiconductor chip 60 are placed on ones of the connecting portions C of the wiring component 40, and the solders 60b of the second connection terminals T2 of the first semiconductor chip 60 is placed on ones of the pads P of the wiring board 1.

Similarly, the second semiconductor chip 70 is fixed to the chip mounter (not shown). Then, the second semiconductor chip 70 is placed on the wiring board 1 and the other end portion of the wiring component 40 so as to be across the wiring component 40 from the first semiconductor chip 60.

Referring to the reduced plan view of FIG. 8 in addition to FIG. 10, at this time, the solders 60b of the first connection terminals T1 of the second semiconductor chip 70 are placed on the other connecting portions C of the wiring component 40, and the solders 60b of the second connection terminals T2 of the second semiconductor chip 70 are placed on the other pads P of the wiring board 1.

Thereafter, reflow heating treatment is performed. Thereby, the first connection terminals T1 of the first semiconductor chip 60 are connected to the ones of the connecting portions C of the wiring component 40 through the solders 60b. Simultaneously, the second connection terminals T2 of the first semiconductor chip 60 are connected to the ones of the pads P of the wiring board 1 through the solders 60b.

Further simultaneously, the first connection terminals T1 of the second semiconductor chip 70 are connected to the other connecting portions C of the wiring component 40 through the solders 60b. At the same time, the second connection terminals T2 of the second semiconductor chip 70 are connected to the other pads P of the wiring board 1 through the solders 60b.

In the case where Sn—Ag solder is used as the solders 60b of the first and second connection terminals T1, T2 of the first and second semiconductor chips 60, 70, the reflow heating treatment is performed at a temperature of about 245° C.

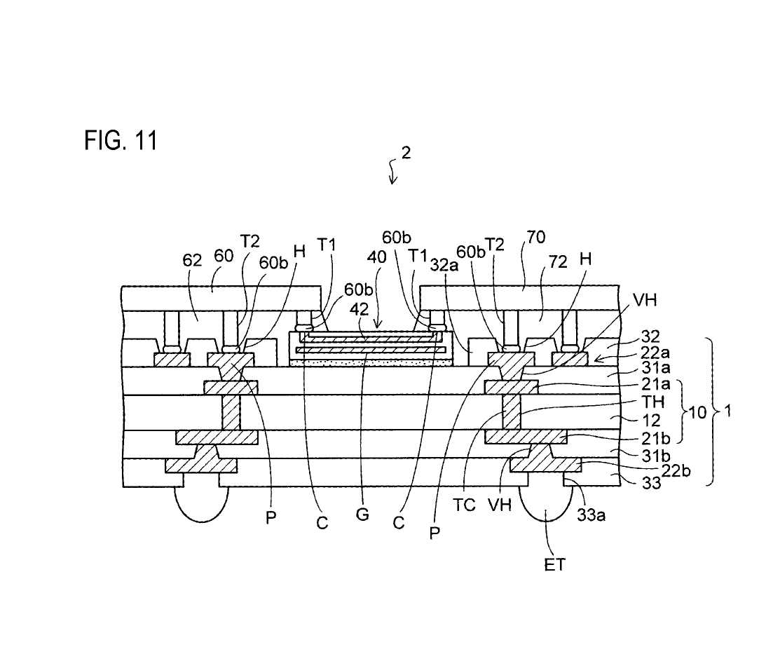

As shown in FIG. 11, thereafter, gaps among the first semiconductor chip 60, the wiring board 1, and the wiring component 40 are filled with an underfill resin 62. Similarly, gaps among the second semiconductor chip 70, the wiring board 1, and the wiring component 40 are filled with an underfill resin 72.

Furthermore, for example, solder balls are mounted on the connecting portions of the second wiring layer 22b on the lower surface side of the core substrate 10. Thereby, external connection terminals ET are formed.

As a result, the electronic component device 2 according to the exemplary embodiment is obtained. In the case where the core substrate 10 is a large board for manufacturing multiple products, the wiring board 1 is divided so as to obtain production regions.

In the electronic component device 2 according to the exemplary embodiment, as shown in FIG. 11, the first connection terminals T1 of the first semiconductor chip 60 have the relatively lower height and are connected through the solders 60b to the ones of the connecting portions C of the wiring component 40, which is mounted on the wiring board 1 of FIG. 5.

The second connection terminals T2 of the first semiconductor chip 60 have the relatively higher height and are connected through the solders 60b to the ones of the pads P of the wiring board 1 of FIG. 5.

As described above, the wiring component 40 is mounted in the insulating layer 31a and in the opening 32a of the solder resist layer 32. As compared with the case where the wiring component 40 is mounted on the solder resist layer 32, therefore, the level of the upper surfaces of the connecting portions C of the wiring component 40 can be decreased by the thickness of the second wiring layer 22a (pads P) and the thickness of the solder resist layer 32.

Therefore, the level difference between the pads P of the wiring board 1 and the connecting portions C of the wiring component 40 can be made small.

Consequently, the height of the second connection terminals T2 of the first semiconductor chip 60 (which are higher than the first connection terminals T1 of the first semiconductor chip 60) can be lowered.

The following case will be considered. That is, similarly to the preliminary matters, dimensions are set so that the thickness of the wiring component 40 is 50 μm; that of the adhesive agent 14 is 10 μm; that of the pads P of the wiring board 1 is 15 μm; and that of the solder resist layer 32 on the pads P is 20 μm.

In the case where the respective elements of the exemplary embodiment have the above-mentioned thicknesses, the height from the upper surfaces of the pads P of the wiring board 1 to those of the connecting portions C of the wiring component 40 is as low as about 45 μm.

As described above, the height of the higher-height second connection terminals T2 of the first semiconductor chip 60 can be made lower. Even if the pitch of connection terminals of a semiconductor chip is narrowed, therefore, the connection terminals can be easily formed.

As described above, in mounting the wiring component 40, the wiring component 40 is adjusted to the predetermined level, which is within the design specification, using the level of the upper surfaces of the pads P of the wiring board 1 as the reference. Therefore, the second connection terminals T2 of the first semiconductor chip 60 can be connected at high yield to the pads P of the wiring board 1. Thus, the reliability of the connection can be ensured.

Even if the height of the second connection terminals T2 of the first semiconductor chip 60 somewhat varies, the variation can be absorbed by the solders 60b provided at the distal ends of the second connection terminals T2.

Also, the second semiconductor chip 70 is mounted in the similar manner so as to be across the wiring component 40 from the first semiconductor chip 60. The lower-height first connection terminals T1 of the second semiconductor chip 70 are connected through the solders 60b to the other connecting portions C of the wiring component 40 mounted on the wiring board 1.

The higher-height second connection terminals T2 of the second semiconductor chip 70 are connected to the other pads P of the wiring board 1 through the solders 60b.

Similarly to the first semiconductor chip 60, in the second semiconductor chip 70, the second connection terminals T2 are connected to the pads P of the wiring board 1 with high reliability.

In this manner, the first semiconductor chip 60 and the second semiconductor chip 70 are connected to each other through the fine internal wiring layers 42 of the wiring component 40.

In the electronic component device 2 according to the exemplary embodiment, the first semiconductor chip 60 and the second semiconductor chip 70 are connected to each other while the wiring component 40 incorporating the fine internal wiring layers 42 is placed only in the region between the first and second semiconductor chips 60, 70.

As compared with the case where fine wirings are formed on the whole of the core substrate 10, the manufacturing cost can be reduced. Also, since the wiring component 40 is mounted on the wiring board 1, the manufacturing cost can be made lower than that of a method in which a wiring component is embedded in a cavity formed in a wiring board.

Furthermore, as described above, the step between the pads P of the wiring board 1 and the wiring component 40 can be made small. Therefore, the reliability of the connections between (i) the first and second semiconductor chips 60, 70 and (ii) the wiring board 1 and the wiring component 40 can be ensured.

In the above-described exemplary embodiment, the semiconductor chips are exemplarily used as the electronic components. However, various other electronic components selected from capacitor elements, resistor elements, inductor elements, and the like may be mounted on the wiring board.

### CLAUSES

This disclosure further encompasses various exemplary embodiments, for example, described below.

1. An electronic component device comprising:

a first insulating layer on which a mounting region is defined;

a wiring layer formed on the first insulating layer except the mounting region;

a second insulating layer that is formed on the first insulating layer, is formed with an opening on the mounting region of the first insulating layer, and is formed with first and second connection holes on the wiring layer;

a wiring component that is mounted on the first insulating layer in the opening of the second insulating layer via an adhesive agent;

one connecting portion and another connecting portion that are disposed on an upper surface side of the wiring component; and

an internal wiring layer that is formed inside the wiring component and is connected to the one connecting portion and said another connecting portion.

2. The electronic component device of the clause 1, wherein the second insulating layer is a solder resist layer.

3. The electronic component device of the clause 1, a level of an upper surface of the wiring component is higher than that of an upper surface of the wiring layer.

4. A method for manufacturing an electronic component device, the method comprising:

obtaining a wiring board, the obtaining comprising
forming a wiring layer on a first insulating layer including a mounting region on an upper surface thereof, except the mounting region,
forming a second insulating layer on the first insulating layer, the second insulating layer being formed with an opening in the mounting region, the second insulating layer including first and second connection holes on the wiring layer, and
mounting a wiring component in the mounting region and in the opening of the second insulating layer, the wiring component comprising first and second connecting portions;

connecting a first electronic component to the first connecting portion of the wiring component and to the wiring layer in a first connection hole of the wiring board; and

connecting a second electronic component to the second connecting portions of the wiring component and to the wiring layer in a second connection hole of the wiring board.

5. The method of the clause 4, wherein in the mounting the wiring component,

the wiring component is mounted on the first insulating layer through an adhesive agent, and

a level of an upper surface of the wiring component is adjusted to a predetermined level, using a level of an upper surface of the wiring layer as a reference.

6. The method of the clause 4 or the clause 5, wherein the second insulating layer is a solder resist layer.

7. A method for manufacturing a wiring board, the method comprising:

forming a wiring layer on a first insulating layer in which a mounting region is defined, except the mounting region;

forming a second insulating layer on the first insulating layer, the second insulating layer being formed with an opening on the mounting region; and

mounting a wiring component in the mounting region and in the opening of the second insulating layer.

8. The method of the clause 7, wherein, in the mounting the wiring component,

the wiring component is mounted on the first insulating layer through an adhesive agent, and

a level of an upper surface of the wiring component is adjusted to a predetermined level, using a level of an upper surface of the wiring layer as a reference.

9. The method of the clause 7 or the clause 8, wherein the second insulating layer is a solder resist layer.

What is claimed is:

1. An electronic component device comprising:
a first insulating layer including a mounting region on an upper surface thereof;
a wiring layer formed on the first insulating layer except the mounting region;
a second insulating layer that is formed on the first insulating layer, is formed with an opening in the mounting region, and is formed with first and second connection holes on the wiring layer;
a wiring component that is mounted in the mounting region and in the opening of the second insulating layer and includes first and second connecting portions;
a first electronic component that is connected to the first connecting portion of the wiring component and is connected to the wiring layer in the first connection hole; and
a second electronic component that is connected to the second connecting portion of the wiring component and is connected to the wiring layer in second connection hole.

2. The electronic component device of claim 1, wherein
the wiring component is mounted on the first insulating layer through an adhesive agent,
the wiring component comprises
an internal wiring layer therein,
an upper surface, and
a lower surface that is opposite from the upper surface, the lower surface of the wiring component and the adhesive agent being disposed between the upper surface of the wiring component and the upper surface of the first insulating layer,
distances between the first and second connecting portions and the upper surface of the wiring component are equal to less than a distance between the internal wiring layer and the upper surface of the wiring component, and
the first and second connecting portions are connected to the internal wiring layers.

3. The electronic component device of claim 1, wherein
each of the first and second electronic components comprises
a first connection terminal including a copper pillar, and
a second connection terminal including a copper pillar,
a height of the first connection terminals are lower than that of the second connection terminals, and
the first connection terminal of the first electronic component is connected to the first connecting portion of the wiring component,
the first connection terminal of the second electronic component is connected to the second connecting portion of the wiring component,
the second connection terminal of the first electronic component is connected to the wiring layer in the first connection hole, and
the second connection terminal of the second electronic component is connected to the wiring layer in the second connection hole.

4. The electronic component device of claim 1, wherein the second insulating layer comprises a solder resist layer.

5. The electronic component device of claim 1, wherein a level of an upper surface of the wiring component is higher than that of the upper surface of the wiring layer.

6. The electronic component device of claim 1, wherein the wiring component is a silicon-based wiring component.

7. The electronic component device of claim 1, further comprising a wiring board, wherein
the wiring board comprises
the first insulating layer,
the wiring layer,
the second insulating layer,
the wiring component,
another wiring layer that, the first insulating layer being disposed between the wiring layer and said another wiring layer, and
a third insulating layer that is formed on said another wiring layer and is formed with an opening,
said another wiring layer is exposed through the opening of the third insulating layer to an outside of the wiring board,
the wiring layer and said another wiring layer are electrically connected to each other.

8. The electric component device of claim 7, wherein
the wiring board further comprises a core substrate,
the core substrate is disposed between the first insulating layer and from said another wiring layer,
the core substrate comprises an upper surface and a lower surface that is opposite from the upper surface,
the core substrate is formed with a through hole that extends from the upper surface of the core substrate to the lower surface of the core substrate, and
the wiring layer and said another wiring layer are electrically connected to each other through a conductor provided in the through hole.

9. The electronic component device of claim 1, wherein
the wiring component comprises an internal wiring layer therein, and
a pitch of wirings in the internal wiring layer is narrower than that of wirings in the wiring layer.
